(19) United States
(12) Patent Application Publication
(10) Pub. No.: US 2009/0026580 A1
(43) Pub. Date: Jan. 29, 2009

(54) Semiconductor Device and Manufacturing Method

(76) Inventor: Karl Malachowski, Dresden (DE)

Correspondence Address: SLATER & MATSIL, L.L.P., 17950 PRESTON ROAD, SUITE 1000, DALLAS, TX, 75252, US

(21) Appl. No.: 11/781,740

(22) Filed: Jul. 23, 2007

(51) Int. Cl. H01L 21/34; H01L 29/00

(52) U.S. Cl. 257/607; 438/460; 438/510; 438/514; 438/542; 257/E29.001; 257/E21.459

(57) ABSTRACT

A semiconductor device and its manufacturing method are disclosed. The semiconductor device includes at least one integrated circuit on a semiconductor substrate having an active side and a back side. The lattice constant of the semiconductor material is increased. The manufacturing method includes stretching the semiconductor lattice in near-surface areas of the back side of the semiconductor substrate.

### TECHNICAL FIELD

The invention relates to a semiconductor device and its manufacturing method.

### BACKGROUND

A semiconductor device, as used hereinafter, comprises at least one integrated circuit on a semiconductor substrate and may, therefore, be a wafer comprising a multitude of integrated circuits, or a single chip singulated from such wafer, or an electronic component or assembly comprising one or more of such chips.

### SUMMARY OF THE INVENTION

In a preferred embodiment, a semiconductor device includes at least one integrated circuit on a semiconductor substrate having an active side and a back side. The lattice constant of the semiconductor material is increased.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows the experimental results of a carrier lifetime measurement, performed on a conventional silicon wafer;

FIG. 2 shows the effect of an increased average carrier lifetime for a silicon wafer made according to the described method; and

FIGS. 3a-3c show an exemplary embodiment of the described method for manufacturing the improved semiconductor device.

### DETAILED DESCRIPTION OF ILLUSTRATIVE EMBODIMENTS

The development of packages with multi chip stacks requires thinning and stress release processes for every wafer to satisfy the overall package height. The thinner the wafer is, the more important is the back side quality of the wafer because of its influence on the electrical characteristics of the electronic device. On an atomic scale, stretching the semiconductor lattice, which leads to an increased interatomic distance, can improve the movement of electrons. This, in turn, leads to a better chip performance (e.g., higher switching frequencies), and lower energy consumption. Therefore, a semiconductor device, comprising at least one integrated circuit on a semiconductor substrate having an active side and a back side is disclosed, wherein the lattice constant of the semiconductor material is elevated. Furthermore, a manufacturing method for the disclosed semiconductor device is disclosed herein.

The lattice constant of a material refers to the distance between unit cells in a crystal lattice. Lattices in three dimensions generally have three lattice constants, referred to as a, b, and c. However, in the special case of cubic crystal structures, all of the constants are equal and one only refers to a. Similarly, in hexagonal crystal structures, the a and b constants are equal, and one refers to the a and c constants only. As lattice constants have the dimension of length, their SI unit is the meter. For instance, the lattice constant of Silicon is 0.543 nm.

An elevated, or increased, lattice constant may be obtained by stretching the semiconductor lattice in near-surface areas of the back side of the chip. In one embodiment, the stretching is effected by changing the near-surface semiconductor material in a chemical reaction. One example of such chemical reaction is the oxidation of the semiconductor material (i.e., to compound the semiconductor material with oxygen) in near-surface areas of the back side of the chip. Another example chemical reaction is carbidization of the semiconductor material (i.e., to compound the semiconductor material with carbon) in near-surface areas of the back side of the chip. Other types of chemical reactions, such as nitridation (i.e., to compound the semiconductor material with nitrogen), may be used to generate the described effect. As the lattice constant in the near-surface areas is elevated with the conversion of the semiconductor material in the chemical reaction, the lattice in deeper layers of the semiconductor material is strained as well, leading to the improved electrical properties described above.

In another embodiment, the stretching is effected by doping the semiconductor material in near-surface areas of the back side of the substrate. In semiconductor production, doping refers to the process of intentionally introducing impurities into an extremely pure semiconductor in order to change its properties, e.g., electrical properties. One example of such doping is the ion implantation of a dopant material in near-surface areas of the back side of the chip. Another example is diffusion of a dopant material in near-surface areas of the back side of the substrate. As the lattice constant in the near-surface areas is elevated with the intrusion of dopant atoms, the lattice in deeper layers of the semiconductor material is strained as well, leading to the improved electrical properties described above.

For the group IV semiconductors such as silicon, germanium, and silicon carbide, possible dopant materials are group III or group V elements. Boron, arsenic, phosphorus and gallium may be dopant materials where the semiconductor material of the substrate is silicon. By doping pure silicon with group V elements such as phosphorus, extra valence electrons are added which become unbonded from individual atoms and allow the compound to be an electrically conductive, n-type semiconductor. Doping with group III elements, such as boron, which are missing the fourth valence electron creates “broken bonds”, or holes, in the silicon lattice that are free to move. This is an electrically conductive, p-type semiconductor.

In another embodiment, the stretching is effected by depositing a layer of material of a higher lattice constant on the back side of the substrate. For instance, the material of a higher lattice constant may be deposited in a CVD or PVD process. In an embodiment, the higher lattice constant material layer is deposited epitaxially. Epitaxial films may be grown from gaseous or liquid precursors. Because the substrate acts as a seed crystal, the deposited film takes on a lattice structure and orientation identical to those of the substrate. This is different from other thin-film deposition methods which deposit polycrystalline or amorphous films, even on single-crystal substrates.

Epitaxy may also be used to grow a layer of pre-doped semiconductor material on the back side of the semiconductor substrate. Deposition of the higher lattice constant material may be done using vapor-phase epitaxy (VPE), a modification of chemical vapor deposition (CVD). Molecular-beam epitaxy (MBE), atomic layer deposition (ALD), and liquid-phase epitaxy (LPE) may also be used. An epitaxial layer of higher lattice constant material can also be doped during deposition by adding impurities to the source gas, such as arsine, phosphine or diborane. The concentration of an impurity in the gas phase determines its concentration in the deposited film. As in CVD, impurities change the deposition rate. Additionally, the high temperatures at which CVD is performed may allow dopants to diffuse into the growing layer from other layers in the wafer (“autodoping”). Conversely, dopants in the source gas may diffuse into the substrate. As the lattice constant in the near-surface areas is elevated during deposition and/or doping of the higher lattice constant material, the lattice in deeper layers of the semiconductor material is strained as well, leading to the improved electrical properties described above.

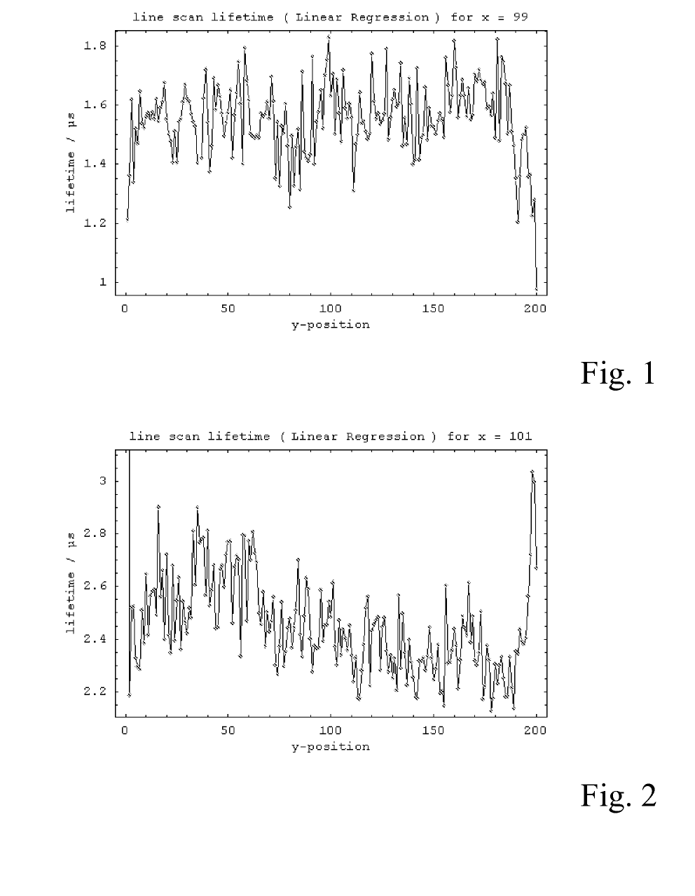

In FIG. 1, a first diagram shows the carrier lifetime in microseconds, as measured across a 200 mm silicon wafer which has been manufactured according to conventional technology. The wafer has been thinned in a backgrinding process to a thickness of 75 micrometers and, subsequently, has been subjected to a plasma-assisted stress relief treatment. The diagram shows an average carrier lifetime of approximately 1.5 microseconds.

In FIG. 2, a second diagram shows in an analogous manner the carrier lifetime in microseconds, as measured across a 200 mm silicon wafer which has been manufactured according to the method described herein. The wafer has been thinned in a backgrinding process to a thickness of 75 micrometers (or less) and, subsequently, has been subjected to a plasma-assisted stress relief treatment. Following the stress relief treatment, however, this wafer has been further treated in an oxidation process. A near surface layer of 25 nm to 75 nm (e.g., 50 nm) in thickness of the substrate material on the wafer back side, has been converted to silicon oxide, with the effect, that the average carrier life time is approximately 2.3 microseconds, that is, approximately 50% higher than in the conventional wafer of FIG. 1.

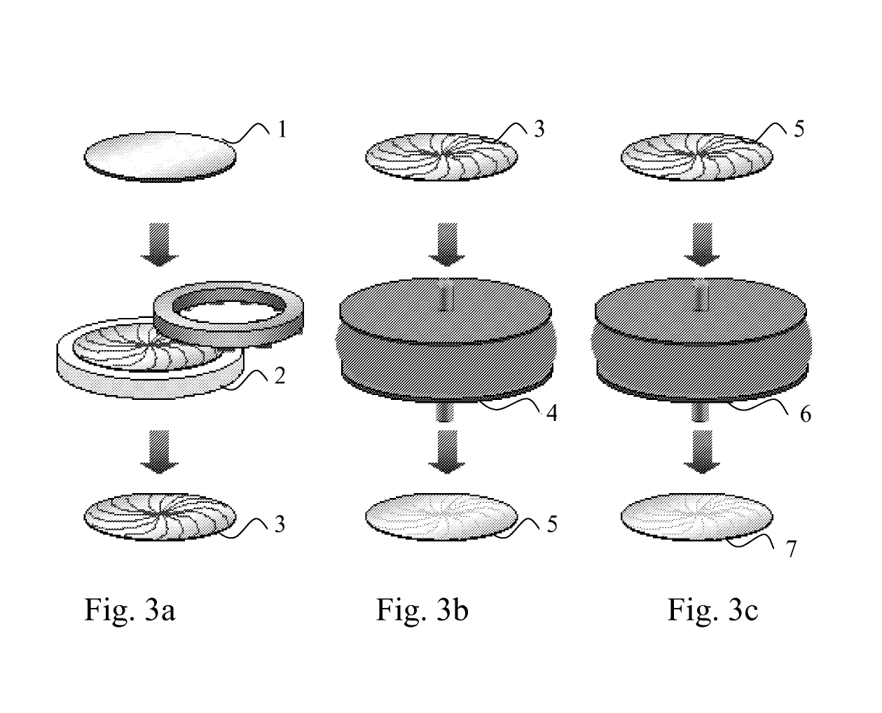

FIG. 3, which includes FIGS. 3a, 3b and 3c, shows, from left to right, three steps of a manufacturing method for semiconductor devices. After the microelectronic structures have been formed on the active side of the substrate 1, for instance, a wafer carrying a matrix array of semiconductor chips, the back side of the wafer is thinned by grinding, wet etching or dry etching it in an appropriate thinning machinery 2, resulting in a thinned substrate 3 (FIG. 3a). Then, the back side of the thinned substrate 3 is processed for stress relief with dry and/or wet etching/polishing in an appropriate stress relief machinery 4, resulting in a stress relieved substrate 5 (FIG. 3b). In an additional step, near surface areas of the back side of the stress relieved substrate 5 are oxidized in an O₂ plasma environment of an appropriate oxidization machinery 6, resulting in an improved semiconductor device 7 (FIG. 3c). After this step, the improved semiconductor device (i.e., the wafer) can be further processed as would be the case in conventional technology. Such further processing may involve singulating the individual chips into so-called dice, using the dice in the assembly of packages, and so on.

What is claimed is:

1. A semiconductor device, comprising at least one integrated circuit on an active side of a semiconductor substrate, the semiconductor substrate also including a back side, wherein a lattice constant of a semiconductor material is increased at the back side relative to a front side.

2. The semiconductor device of claim 1, wherein the semiconductor substrate comprises a wafer that includes a plurality of integrated circuits on its active side.

3. The semiconductor device of claim 1, wherein the semiconductor substrate comprises the substrate of a single integrated circuit.

4. The semiconductor device of claim 1, wherein a semiconductor lattice is stretched in near-surface areas of the back side of the semiconductor substrate and, as a result, the lattice in deeper layers of the semiconductor material is strained.

5. The semiconductor device of claim 4, wherein the stretched lattice comprises an oxide of the semiconductor material.

6. The semiconductor device of claim 4, wherein the stretched lattice comprises a nitride of the semiconductor material.

7. The semiconductor device of claim 4, wherein the stretched lattice comprises a dopant.

8. The semiconductor device of claim 4, wherein the stretched lattice comprises an additional layer of higher lattice constant material deposited on the back side of the semiconductor substrate.

9. A method for manufacturing a semiconductor device, comprising:
forming active devices at a front side of a semiconductor substrate; and
stretching a semiconductor lattice in near-surface areas of a back side of the semiconductor substrate, the back side opposite the front side.

10. The method of claim 9, further comprising:
thinning the semiconductor substrate;
subjecting the thinned substrate to a stress relief treatment, wherein the semiconductor lattice is stretched in near-surface areas of the back side of the stress relief treated substrate.

11. The method of claim 9, wherein stretching the semiconductor lattice involves changing the near-surface semiconductor material in a chemical reaction.

12. The method of claim 11, wherein the chemical reaction comprises oxidation, carbidization or nitridation of the back side of the semiconductor substrate.

13. The method of claim 9, wherein stretching the semiconductor lattice comprises doping the semiconductor material in near-surface areas of the back side of the substrate.

14. The method of claim 13, wherein doping comprises implanting or diffusing a dopant material.

15. The method of claim 14, wherein the dopant material comprises a group III or group V element.

16. The method of claim 9, wherein stretching the semiconductor lattice comprises depositing a layer of material of a higher lattice constant on the back side of the substrate.

17. The method of claim 16, wherein depositing a layer of material of a higher lattice constant comprises doping the deposited material.

18. The method of claim 16, wherein depositing a layer of material of a higher lattice constant comprises depositing an epitaxial layer of higher lattice constant material that is doped during deposition.

19. The method of claim 18, wherein the epitaxial layer is deposited from a gaseous phase.

20. The method of claim 19, wherein impurities are added to a source gas during deposition of the epitaxial layer.

21. A method of making an integrated circuit, the method comprising:
forming active circuits at a front side of a semiconductor wafer;
after forming the active circuits, thinning the semiconductor wafer from a back side, the back side opposite the front side;
after thinning the semiconductor wafer, subjecting the back side to a stress relief treatment;
after subjecting the back side to the stress relief treatment, stressing the back side of the semiconductor wafer; and
singulating the semiconductor wafer into a plurality of integrated circuit chips.

22. The method of claim 21, wherein thinning the semiconductor wafer comprises grinding the back side of the semiconductor wafer.

23. The method of claim 22, wherein thinning the semiconductor wafer comprises thinning the wafer to a thickness of 75 micrometers or less.

24. The method of claim 21, wherein the stress relief treatment comprises a plasma-assisted stress relief treatment.

25. The method of claim 21, wherein stressing the back side comprises performing an oxidation process.

26. The method of claim 25, wherein performing the oxidation process forms a near surface layer silicon oxide on the back side of the semiconductor wafer, the layer of silicon oxide having a thickness between about 25 nm and 75 nm.

27. The method of claim 21, wherein stressing the back side comprises performing a nitridation process.

28. The method of claim 21, wherein stressing the back side comprises doping the back side of the semiconductor wafer.

29. The method of claim 21, wherein stressing the back side comprises depositing a layer over the back side of the semiconductor wafer.
